(19) United States
(12) Patent Application Publication
(10) Pub. No.: US 2013/0032947 A1
(43) Pub. Date: Feb. 7, 2013

(54) SEMICONDUCTOR PACKAGE AND METHOD OF MANUFACTURING THE SAME

(71) Applicants: Sang-sick Park, Seoul (KR); Tae-je Cho, Hwaseong-si (KR); Sang-wook Park, Hwaseong-si (KR); Teak-hoon Lee, Hwaseong-si (KR); Kwang-chul Choi, Suwon-si (KR); Myung-sung Kang, Hwaseong-si (KR)

(72) Inventors: Sang-sick Park, Seoul (KR); Tae-je Cho, Hwaseong-si (KR); Sang-wook Park, Hwaseong-si (KR); Teak-hoon Lee, Hwaseong-si (KR); Kwang-chul Choi, Suwon-si (KR); Myung-sung Kang, Hwaseong-si (KR)

(21) Appl. No.: 13/482,415

(22) Filed: May 29, 2012

(30) Foreign Application Priority Data
Aug. 5, 2011 (KR) 10-2011-0078202

(51) Int. Cl. H01L 23/48; H01L 21/56

(52) U.S. Cl. 257/774; 257/777; 438/127; 257/E23.01; 257/E21.502

(57) ABSTRACT

A semiconductor package that stably protects an internal semiconductor chip from external shocks, and a method of manufacturing the semiconductor package is disclosed. The semiconductor package includes a first semiconductor chip including a first body layer having a first surface, a second surface, and a lateral surface between the first surface and the second surface, and a first protective layer that exposes an edge portion of the first surface and forms a step difference with the first surface; an encapsulation structure that covers a lateral surface of the first body layer and the edge portion of the first surface so as to encapsulate the first semiconductor chip to have a locking structure; and a first conductive terminal formed on the first body layer through the protective layer.

### CROSS-REFERENCE TO RELATED APPLICATIONS

This application claims the benefit of priority to Korean Patent Application No. 10-2011-0078202, filed on Aug. 5, 2011, in the Korean Intellectual Property Office, the disclosure of which is incorporated herein in its entirety by reference.

### BACKGROUND

This disclosure relates to a semiconductor package having a encapsulation locking structure and a method of manufacturing the semiconductor package.

In general, a semiconductor package is manufactured by performing a packaging process on semiconductor chips formed by performing various wafer semiconductor processes. The semiconductor package includes a semiconductor chip, a printed circuit board (PCB) on which the semiconductor chip is mounted, a bonding wire or bump for electrically connecting the semiconductor chip and the PCB to each other, and an encapsulation member for encapsulating the semiconductor chip. Thus, there is a need for a stable structure for obtaining high integration of the semiconductor package and for protecting the internal semiconductor chip from external physical and electrical shocks.

### SUMMARY

The disclosed embodiments describe a semiconductor package that stably protects an internal semiconductor chip from external shocks, and a method of manufacturing the semiconductor package.

The embodiments also describe a semiconductor package including two stacked semiconductor chips, the semiconductor package stably protecting an internal semiconductor chip from external shocks without limitation of a scribe lane (SL), and a method of manufacturing the semiconductor package.

According to one embodiment, there is provided a semiconductor package including a first semiconductor chip including a first body layer having a first surface, a second surface, and a lateral surface between the first surface and the second surface, and a first protective layer that exposes an edge portion of the first surface and forms a step difference with the first surface; an encapsulation structure that covers a lateral surface of the first body layer and the edge portion of the first surface so as to encapsulate the first semiconductor chip to have a locking structure; and a first conductive terminal formed on the first body layer through the protective layer.

A bottom surface of the encapsulation member may be coplanar with a bottom surface of the first protective layer. A third surface forming a step difference with the first surface may be formed on the first body layer, the third surface, the first surface, and a first protective layer may constitute a double step difference, and the encapsulation structure may cover the third surface.

The semiconductor package may further include at least one upper semiconductor chip formed on the first semiconductor chip. The at least one upper semiconductor chip may include a single second semiconductor chip, the semiconductor package may include a second conductive terminal formed on a lower surface of the second semiconductor chip, the first semiconductor chip may include a through silicon via that is electrically connected to the first conductive terminal, the second semiconductor chip may be electrically connected to the TSV through the second conductive terminal, the encapsulation structure may be filled in a space between the first and second semiconductor chips, and the encapsulation structure may cover lateral and top surfaces of the second semiconductor chip.

The encapsulation structure may include an underfill that is filled in a space between the first semiconductor chip and a first chip of the at least one upper semiconductor chip, and an external encapsulation member that covers at least part of the underfill. The external encapsulation member may cover lateral surfaces of the first semiconductor chip and lateral surfaces of at least the first chip of the at least one upper semiconductor chip, an upper surface of an upper-most semiconductor chip of the at least one upper semiconductor chip, and an edge portion of the first surface.

The first protective layer may be a nitride-based protective layer or a PSPI protective layer, and the encapsulation layer may be formed of a polymer. The edge portion of the first surface may correspond to a scribe lane of a wafer.

According to another embodiment, there is provided a semiconductor device including at least a first semiconductor chip, the first semiconductor chip including a top surface, a bottom surface, and a lateral surface between the bottom surface and top surface, the first semiconductor chip further including a protective layer at the bottom surface. The protective layer is not formed at a first edge portion of the bottom surface of the first semiconductor chip adjacent the lateral surface. The semiconductor device includes an encapsulation structure, the encapsulation structure covering the first edge portion of the bottom surface of the first semiconductor chip, and at least a first part of the lateral surface of the first semiconductor chip.

According to another embodiment, a method of manufacturing a semiconductor device is disclosed. The method includes forming at least a first semiconductor chip, the first semiconductor chip including a top surface, a bottom surface, and a lateral surface between the bottom surface and top surface, wherein forming the first semiconductor chip includes forming a protective layer at the bottom surface of the semiconductor chip, wherein the protective layer does not cover at least an edge portion of the bottom surface of the first semiconductor chip. The method further includes forming an encapsulation structure to cover the edge portion of the bottom surface of the first semiconductor chip, and at least a first part of the lateral surface of the first semiconductor chip.

### BRIEF DESCRIPTION OF THE DRAWINGS

Exemplary embodiments will be more clearly understood from the following detailed description taken in conjunction with the accompanying drawings in which:

FIGS. 1 through 10 are cross-sectional views of exemplary semiconductor packages having a polymer locking structure, respectively, according to various embodiments;

FIGS. 11A through 11G are cross-sectional views for describing an exemplary method of manufacturing the semiconductor package of FIG. 7, according to one embodiment;

FIGS. 12A and 12B are cross-sectional views for describing an exemplary method of forming a semiconductor chip having a double step difference, which is used in the semiconductor package of FIG. 2 or 6, according to one embodiment;

FIGS. 13A through 13C are cross-sectional views for describing an exemplary method of forming a semiconductor chip having a double step difference, which is used in the semiconductor package of FIG. 2 or 6, according to another embodiment;

FIGS. 14 through 17 are cross-sectional views of exemplary semiconductor packages having a polymer locking structures, according to certain embodiments;

FIG. 18 is a block diagram of an exemplary memory card including a semiconductor package according to one embodiment; and

FIG. 19 is a block diagram of an exemplary electronic system including a semiconductor package according to one embodiment.

### DETAILED DESCRIPTION OF THE EMBODIMENTS

Hereinafter, this disclosure will be described in detail by explaining exemplary embodiments with reference to the attached drawings. Reference will now be made in detail to example embodiments, examples of which are illustrated in the accompanying drawings. However, example embodiments are not limited to the embodiments illustrated hereinafter, and the exemplary embodiments herein are just that—examples—and may not describe all possible variations of the invention.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. Unless indicated otherwise, these terms are only used to distinguish one element from another, and may be used simply as a naming convention. For example, a first chip could be termed a second chip, and, similarly, a second chip could be termed a first chip without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Embodiments described herein will be described referring to plan views and/or cross-sectional views by way of ideal schematic views. Accordingly, the exemplary views may be modified depending on manufacturing technologies and/or tolerances. Therefore, the disclosed embodiments are not limited to those shown in the views, but include modifications in configuration formed on the basis of manufacturing processes. Therefore, regions exemplified in figures have schematic properties, and shapes of regions shown in figures exemplify specific shapes of regions of elements, and the specific properties and shapes do not limit aspects of the invention.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Terms such as “same,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

In the drawings, the structure or size of each component is exaggerated for convenience and clarity of illustration and portions unrelated to description are omitted. Like reference numerals indicate like elements throughout the drawings. Terms used therein are only for illustrative purposes and are not intended to limit the scope of the inventive concept defined in the claims.

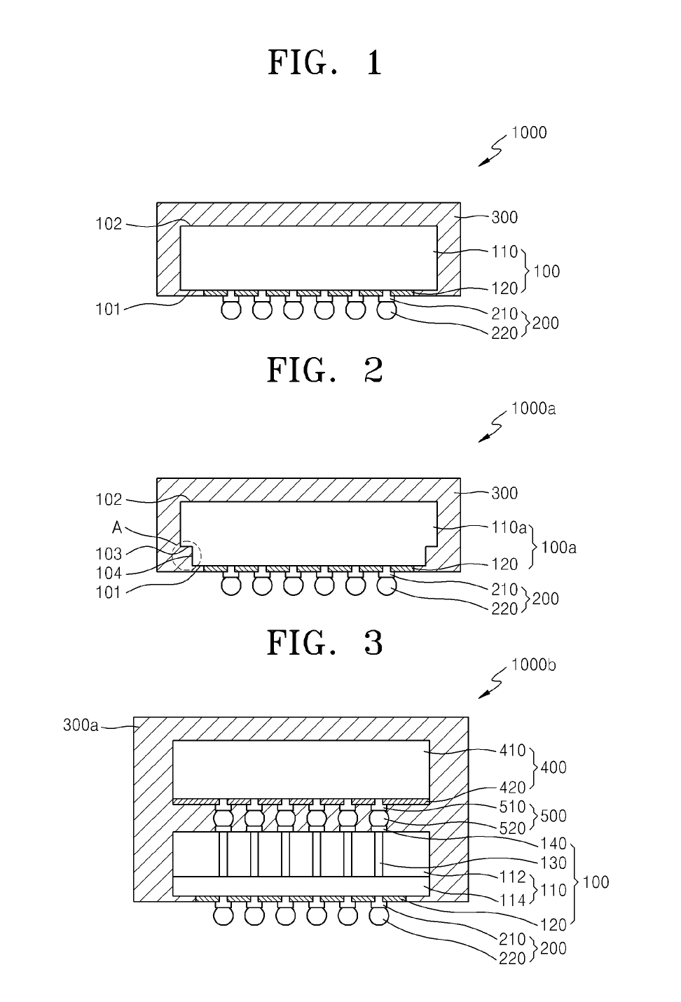

FIGS. 1 through 10 are cross-sectional views of semiconductor packages 1000, 1000a, 1000b, 1000c, 1000d, 1000e, 1000f, 1000g, 1000h, and 1000i having a polymer locking structure, respectively, according to embodiments of the inventive concept.

Referring to FIG. 1, the semiconductor package 1000 may include a semiconductor chip 100, connection members 200, and an encapsulation member 300.

The semiconductor chip 100 may include a body layer 110 and a protective layer 120. The body layer 110 may include a silicon substrate (not shown), an integrated circuit (IC) layer formed on the silicon substrate, an interlayer insulating layer (not shown) covering the IC layer, an intermetal insulating layer (not shown) formed on the interlayer insulating layer and including a plurality of wiring layers formed therein, and the like. The body layer 110 may include a first surface 101 and a second surface 102. The first surface 101 may correspond to a front surface of the semiconductor chip 110, and the second surface 102 may be opposite the first surface 101 and may correspond to a rear surface of the semiconductor chip 110.

In one embodiment, the protective layer 120 is formed on the first surface 101 of the body layer 110, but is not formed on an edge portion of the first surface 101. Thus, the edge portion of the first surface 101 may be exposed without being covered by the protective layer 120. The exposed edge portion of the first surface 101 may be, for example, part of a scribe lane (SL) of a wafer. The SL is a part in which a plurality of semiconductor chips formed on the wafer are divided and may not include any conductive material, such as circuitry for sending or receiving power or signals. The protective layer 120 may not be formed on the SL.

The protective layer 120 may be formed of a material including an oxide layer or a nitride layer, or alternatively, may be formed to have a bilayer structure including a group of materials such as an oxide layer and a nitride layer. For example, the protective layer 120 may be formed of silicon oxide (SiO₂) or silicon nitride (SiNx). The protective layer 120 may be formed of photosensitive polymide (PSPI), and may be referred to as a passivation layer.

Each of the connection members 200 may be a conductive terminal for electrically connecting the semiconductor chip 100 to a device outside the chip, and may include, for example, a bump pad 210 and a bump 220. The bump pad 210 may be formed of a conductive material on the first surface 101 of the body layer 110 through the protective layer 120. In addition, the bump pad 210 may be electrically connected to the wiring layers formed in the intermetal insulating layer. Thus, the bump pad 210 may be electrically connected to the IC layer through the wiring layers, and may be configured to send and receive signals to and from circuitry at the IC layer. An under bump metal (UBM) may be formed on the bump pad 210. The bump pad 210 may be formed of aluminium (Al), copper (Cu), or the like by pulse electroplating or direct current (DC) electroplating. However, the bump pad 210 is not limited to the above materials or methods.

The bump 220 may be formed on the bump pad 210. The bump 220 may be formed of a conductive material such as Cu, Al, gold (Au), solder, or the like. However, a material of the bump 220 is not limited to the above-described material. Bumps 220 may be arranged in an array form. When the bump 220 is formed of solder, the bump 220 may be referred to as a solder bump.

The encapsulation member 300 may be an encapsulation structure that encapsulates the semiconductor chip 100 so as to protect it from external physical and electrical shocks. The encapsulation member 300 may cover a lateral surface of the body layer 110, the second surface 102, and the exposed edge portion of the first surface 101. As such, the encapsulation member 300 covers a lower corner portion of the semiconductor chip 100, including both a lateral side and bottom surface of the semiconductor chip 100 that comprise the lower corner portion. Since the encapsulation member 300 covers the exposed edge portion of the first surface 101, a lower, bottom surface of the encapsulation member 300 may correspond to and be coplanar with a lower, bottom surface of the protective layer 120 (which may be a bottom-most surface of the semiconductor chip 100).

In FIG. 1, the encapsulation member 300 is formed to cover the second surface 102. Alternatively, the encapsulation member 300 may be formed so that an upper, top surface of the encapsulation member 300 may correspond to and be coplanar with an upper, top surface of the second surface 102, without covering the second surface 102. As such, the encapsulation member 300 may be formed to cover only the lateral surface of the body layer 110 and the exposed edge portion of the first surface 101.

The encapsulation member 300 may be formed of a material different from the material that comprises the protective layer 120, such as, for example, a polymer such as resin. For example, the encapsulation member 300 may be formed of an epoxy molding compound (EMC). As such, in one embodiment, the protective layer 120 is formed of a first material, and the encapsulation member 300 is formed of a second material different from the first material. A lateral surface of the encapsulation member 300 may contact a lateral surface of the protective layer 120.

The semiconductor package 1000 is formed so that the encapsulation member 300 may cover the edge portion of the first surface 101 of the body layer 110. Thus, the semiconductor chip 100 is encapsulated by a locking structure, thereby preventing the semiconductor chip 100 from being delaminated due to external stress caused by thermal history so as to stably protect the semiconductor chip 100 from external shocks.

The semiconductor package 1000a of FIG. 2 has a similar structure to that of the semiconductor package 1000 of FIG. 1 except for a body layer 110a. Thus, for convenience of description, the detailed description that has been described with reference to FIG. 1 is omitted or is simply described.

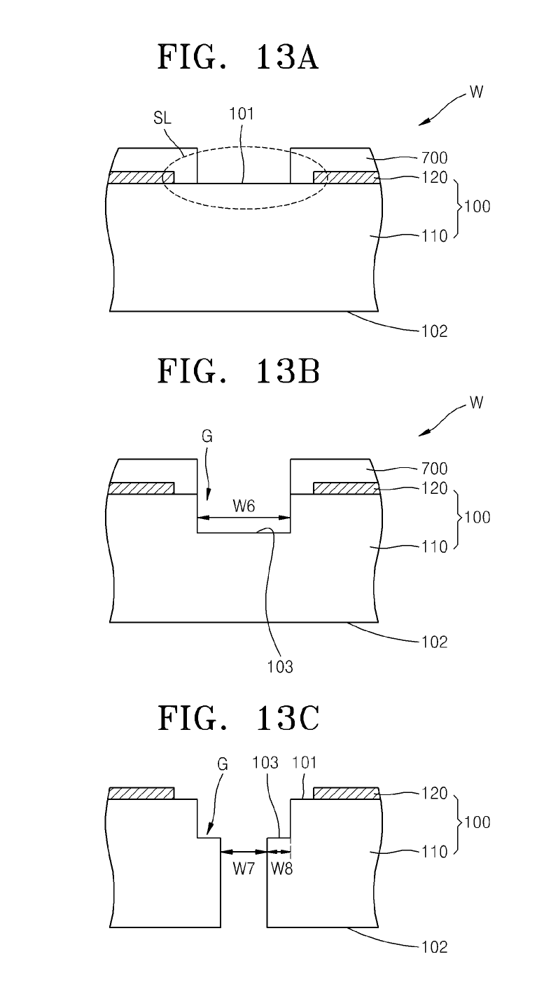

Referring to FIG. 2, in the semiconductor package 1000a, a third surface 103 forming a step difference with respect to the first surface 101 may be formed on a lateral surface of the body layer 110a. In the process, a fourth surface 104 forming a recessed lateral surface of the body layer is also formed (the third surface 103 can also be described as a recessed bottom surface of the body layer 110a). As such, a groove A is formed in the lateral surface of the body layer 110a. The groove A may be a cut groove. In addition, an upper surface of the cut groove A, that is, the third surface 103, may form a step difference with respect to a first surface 101. A method of forming the cut groove A will be described in detail with reference to FIGS. 12A through 13C.

An encapsulation member 300 may be formed to cover the exposed edge portion of the first surface 101 and the third surface 103 and fourth surface 104 of the cut groove A. Thus, a semiconductor chip 100a may be encapsulated by using a dual locking structure. For example, the third surface 103, the first surface 101, and a lower, bottom surface of a protective layer 120 (e.g., a bottom-most surface of the protective layer 120) may constitute a double step difference, and the double step difference may be covered by the encapsulation member 300, thereby the semiconductor chip 100a being encapsulated.

FIG. 3 shows the semiconductor package 1000b including two semiconductor chips, that is, first and second semiconductor chips 100 and 400, unlike the semiconductor packages 1000 and 1000a of FIGS. 1 and 2. For convenience of description, the detailed description that has been described with reference to FIG. 1 is omitted or is simply described.

Referring to FIG. 3, the semiconductor package 1000b may include the first semiconductor chip 100, first connection members 200, the second semiconductor chip 400, second connection members 500, and an encapsulation member 300a.

The first semiconductor chip 100 may include a first body layer 110, a first protective layer 120, through substrate vias (TSVs) 130 (e.g., through silicon vias), and upper pads 140. The first body layer 110 is divided into an upper body layer 112 and a lower body layer 114. The upper body layer 112 may include a silicon substrate, an IC layer, and an interlayer insulating layer covering the IC layer. The lower body layer 114 may be an intermetal insulating layer and may include a plurality of wiring layers formed therein.

The first protective layer 120 may be formed on a lower, bottom surface of the lower body layer 114 and may expose an edge portion of the lower surface of the lower body layer 114. Thus, the first protective layer 120 and the lower surface of the lower body layer 114 may constitute a step difference. The lower surface of the lower body layer 114 may correspond to the first surface 101 of the body layer 110 of the semiconductor package 1000 of FIG. 1. The detailed description of the protective layer 120 of the semiconductor package 1000 of FIG. 1 is the same as that of the first protective layer 120 of FIG. 3.

The TSVs 130 may be electrically connected to the wiring layers formed in the lower body layer 114 through the upper body layer 112. According to one embodiment, each of the TSVs 130 is formed to have a via-middle structure, but is not limited thereto. Thus, the TSV 130 may be formed to have a via-first or via-last structure. For reference, the via-first structure may refer to a structure formed by forming a TSV prior to forming an IC layer in the upper body layer 112, the via-middle structure may refer to a structure formed by forming a TSV prior to forming the wiring layers after forming an IC layer, and the via-last structure may refer to a structure formed by forming a TSV after forming the wiring layers.

The TSVs 130 may be electrically connected to the first connection members 200 through the wiring layers, respectively. When the TSVs 130 have a via-last structure, the TSVs may be connected directly to the first connection members 200.

The upper pads 140 may be formed on an upper, top surface of the upper body layer 112 and may be electrically connected to the TSVs 130. Although not illustrated, an upper protective layer (not shown) may be further formed on the upper body layer 112. In this case, the upper pads 140 may be formed through the upper protective layer. The upper pads 140 may be formed, for example, of alumina or copper, like the bump pads 210.

The first connection members 200 of FIG. 3 may correspond to the connection members 200 of the semiconductor package 1000 of FIG. 1. The first connection members 200 may be electrically connected to the TSVs 130 as described above.

The second semiconductor chip 400 may include a second body layer 410 and a second protective layer 420, like the first semiconductor chip 100. Materials and structures of the second body layer 410 and the second protective layer 420 may be similar to those of the first body layer 110 and the first protective layer 120. In FIG. 3, though the second body layer 410 is showed as a single structure, the second body layer 410 may be showed as an upper body layer and a lower body layer, like the first body layer 110. As shown in FIG. 3, in one embodiment, the second protective layer 420 does not expose an edge portion of a lower, bottom surface of the second body layer 410.

According to the embodiment shown in FIG. 3, the second semiconductor chip 400 does not include any TSV. However, if necessary, the second semiconductor chip 400 may include TSVs. In this case, the TSVs of the second semiconductor chip 400 may be similar to the TSVs 130 of the first semiconductor chip 100.

Each of the second connection members 500 may include second bump pads 510 and second bumps 520. The detailed description of the connection members 200 of the semiconductor package 1000, which has been described with reference to FIG. 1, may be the same with that of the second connection members 500. The second semiconductor chip 400 may be stacked on the first semiconductor chip 100 through the second connection members 500. The IC layer (not shown) formed in the second semiconductor chip 400 may be electrically connected to the first connection members 200 through the second connection member 500, the upper pads 140, the TSVs 130, and the like. The combined connection members and attached upper pads 140 may comprise a set of conductive interconnection terminals for electrically connecting the first semiconductor chip 100 to the second semiconductor chip 400.

An encapsulation member 300a may comprise an encapsulation structure that encapsulates the first semiconductor chip 100 and the second semiconductor chip 400. In more detail, the encapsulation member 300a may be filled in a space formed between the first semiconductor chip 100 and the second semiconductor chip 400 and may cover lateral surfaces of the first semiconductor chip 100 and the second semiconductor chip 400, an upper surface of the second semiconductor chip 400, and the exposed edge portion of the lower body layer 114. Since the encapsulation member 300a covers the exposed edge portion of the lower body layer 114, the semiconductor package 1000b may also have a locking structure.

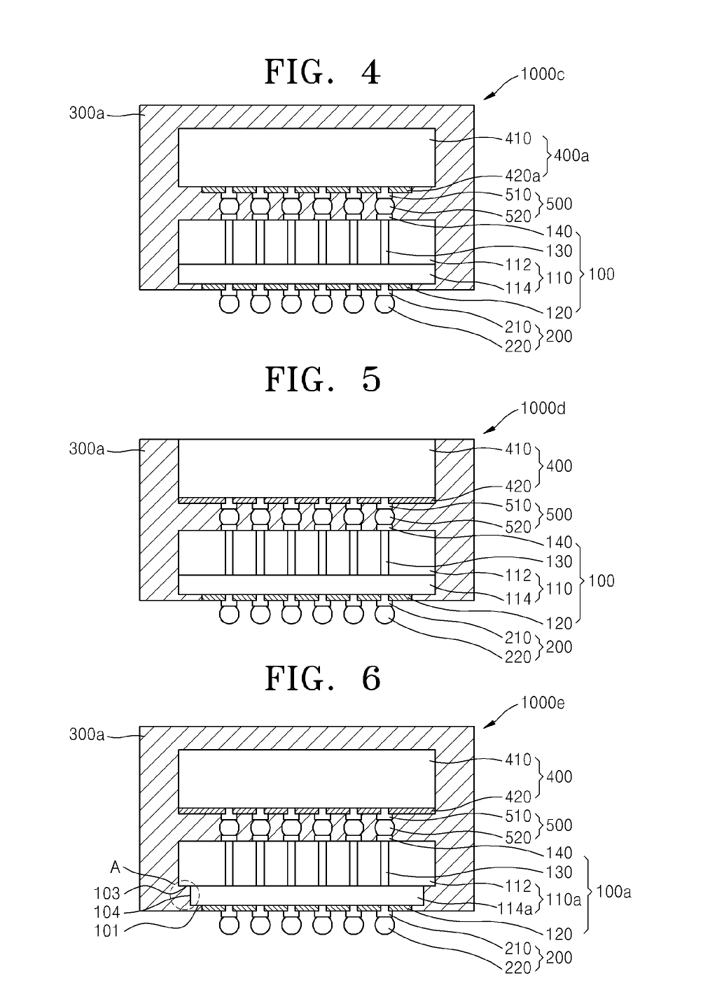

The semiconductor package 1000c of FIG. 4 has a similar structure to that of the semiconductor package 1000b of FIG. 3, except for a second semiconductor chip 400a. Thus, for convenience of description, the detailed description that has been described with reference to FIG. 3 is omitted or is simply described.

Referring to FIG. 4, a second protective layer 420a of the semiconductor package 1000c may have a different structure from that of the second protective layer 420 of the semiconductor package 1000b of FIG. 3. According to the embodiment shown in FIG. 4, the second protective layer 420a may be formed to expose an edge portion of a lower surface of the second body layer 410 so that the lower surface of the second body layer 410 and a lower surface of the second protective layer 420a may constitute a step difference.

As the second protective layer 420a exposes the edge portion of the lower surface of the second body layer 410, an encapsulation member 300a may cover the exposed edge portion of the lower surface of the second body layer 410. Thus, the second semiconductor chip 400a may be encapsulated by the encapsulation member 300a to form a locking structure.

The semiconductor package 1000d of FIG. 5 has a similar structure to that of the semiconductor package 1000b of FIG. 3, except for an encapsulation member 300a. Thus, for convenience of description, the detailed description that has been described with reference to FIG. 3 is omitted or is simply described.

Referring to FIG. 5, in the semiconductor package 1000d, the encapsulation member 300a may not cover an upper, top surface of the second semiconductor chip 400. Since the encapsulation member 300a is not formed on an upper surface of the second semiconductor chip 400, an entire thickness of the semiconductor package 1000d may be reduced. The semiconductor package 1000d having this structure may be formed by forming an encapsulation member and removing a portion of the encapsulation member that remains on the second semiconductor chip 400 by using a back-grinding method. As shown, a top surface of the encapsulation member 300a may be coplanar with a top surface of the second semiconductor chip 400.

The semiconductor package 1000e of FIG. 6 has a similar structure to that of the semiconductor package 1000b of FIG. 3, except for a first semiconductor chip 100a. Thus, for convenience of description, the detailed description that has been described with reference to FIG. 3 is omitted or is simply described.

Referring to FIG. 6, in the semiconductor package 1000e, the first semiconductor chip 100a may include a first body layer 110a, a first protective layer 120, TSVs 130, and upper pads 140. The first body layer 110a may be divided into an upper body layer 112 and a lower body layer 114a. The upper body layer 112 and the lower body layer 114a may have different sizes. That is, like in the semiconductor package 1000a of FIG. 2, a groove A is formed in a lateral surface of the body layer 110a, and thus, a third surface 103, and a fourth surface 104 may be formed to have a step difference with respect to a first surface 101.

According to the embodiment shown in FIG. 6, the upper body layer 112 and the lower body layer 114a may be distinguished based on the third surface 103 and the fourth surface 104 formed through the groove A. In this case, the lower body layer 114a may be an intermetal insulating layer. In the presence of the third surface 103, a lateral surface of the first semiconductor chip 100a may have a double step difference. That is, the third surface 103, the first surface 101, and a lower, bottom surface of the first protective layer 120 may constitute a double step difference.

The encapsulation member 300a may be formed to cover the groove A. Thus, in the semiconductor package 1000e, the encapsulation member 300a may stably encapsulate the first semiconductor chip 100a and the second semiconductor chip 400 through the double step difference formed on the lateral surface of the first semiconductor chip 100a.

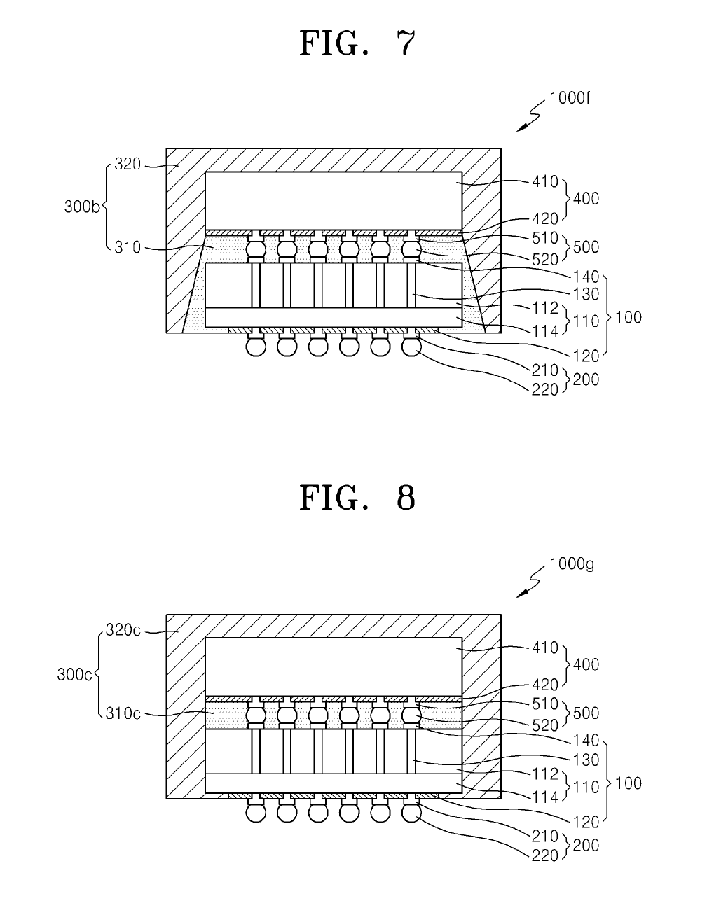

The semiconductor package 1000f of FIG. 7 has a similar structure to that of the semiconductor package 1000b of FIG. 3, except for an encapsulation structure 300b. Thus, for convenience of description, the detailed description that has been described with reference to FIG. 3 is omitted or is simply described.

Referring to FIG. 7, in the semiconductor package 1000f, the encapsulation structure 300b may include an underfill 310 and an external encapsulation member 320.

The underfill 310 may be filled in a space between a first semiconductor chip 100 and a second semiconductor chip 400, that is, a space adjacent a connection portion between upper pads 140 of a first semiconductor chip 100 and a second connection member 500. The underfill 310 may be formed of an underfill resin such as an epoxy resin and may include a silica filler, a flux, or the like. The underfill 310 may be formed of a different material from an external encapsulation member 320, or alternatively, may be formed of the same material as the external encapsulation member 320.

Instead of the underfill 310, a non-conductive film (NCF), an anisotropic conductive film (ACF), an ultraviolet (UV) film, instant adhesives, thermosetting adhesives, laser setting adhesives, supersonic wave setting adhesives, a non-conductive paste (NCP), or the like may be filled in the space between the first semiconductor chip 100 and the second semiconductor chip 400.

As shown in FIG. 7, the underfill 310 may extend from the space between the first semiconductor chip 100 and the second semiconductor chip 400 and may surround the first semiconductor chip 100. Thus, the underfill 310 portion of the encapsulation structure 300b may cover a lateral surface of the first semiconductor chip 100 and the exposed edge portion of the lower surface of the lower body layer 114, as well as part of the top surface of the first semiconductor chip 100. Thus, the lower surface of the underfill 310 may correspond to and be coplanar with the lower surface of a first protective layer 120.

The external encapsulation member 320 may be formed to surround the underfill 310 and the second semiconductor chip 400. For example, the external encapsulation member 320 may cover a lateral surface of the underfill 310, and a lateral surface and upper surfaces of the second semiconductor chip 400. As described above, the external encapsulation member 320 may be formed of a polymer, for example, an epoxy molding compound (EMC). As shown in FIG. 7, the lower surface of the external encapsulation member 320 may correspond to and be coplanar with the lower surface of the underfill 310. Thus, lower surfaces of the underfill 310 and the external encapsulation member 320 forming a lower, bottom surface of the encapsulation structure 300b may correspond to and be coplanar with a lower, bottom surface of a first protective layer 120. As such, the protective layer 120 may be formed of a first material or group of materials, and the encapsulation structure 300b may be formed of a second and third materials, wherein at least one of the second or third materials contacts and covers a lower surface of the semiconductor chip 100, a lateral surface of the protective layer 120, a lateral surface of the semiconductor chip 100, and a top surface of the semiconductor chip 100.

The semiconductor package 1000g of FIG. 8 has a similar structure to that of the semiconductor package 1000f of FIG. 7 except for an encapsulation structure 300c. Thus, for convenience of description, the detailed description that has been described with reference to FIG. 7 is omitted or is simply described.

Referring to FIG. 8, in the semiconductor package 1000g, a structure of the encapsulation structure 300c may be different from the encapsulation structure 300b of the semiconductor package 1000f of FIG. 7. For example, an underfill 310c may be formed in only a space between a first semiconductor chip 100 and a second semiconductor chip 400 and may not surround a lateral surface of the first semiconductor chip 100. In FIG. 8, the underfill 310c corresponds to and is coplanar with lateral surfaces of the first semiconductor chip 100 and the second semiconductor chip 400. Alternatively, if necessary, the underfill 310c may protrude from the lateral surfaces of the first semiconductor chip 100 and the second semiconductor chip 400.

As described with reference to FIG. 7, instead of the underfill 310c, an NCF, an ACF, a UV film, instant adhesives, thermosetting adhesives, laser setting adhesives, supersonic wave setting adhesives, NCP, or the like may be filled in the space between the first semiconductor chip 100 and the second semiconductor chip 400.

Since the underfill 310c is filled in only the space between the first semiconductor chip 100 and the second semiconductor chip 400, an external encapsulation member 320c of the encapsulation structure 300c may cover lateral surfaces of the first semiconductor chip 100, the second semiconductor chip 400 and the underfill 310c, an upper surface of the second semiconductor chip 400, and the exposed edge portion of a lower surface of a lower body layer 114. Thus, a lower surface of the external encapsulation member 320c may correspond to and be coplanar with a lower surface of the first protective layer 120.

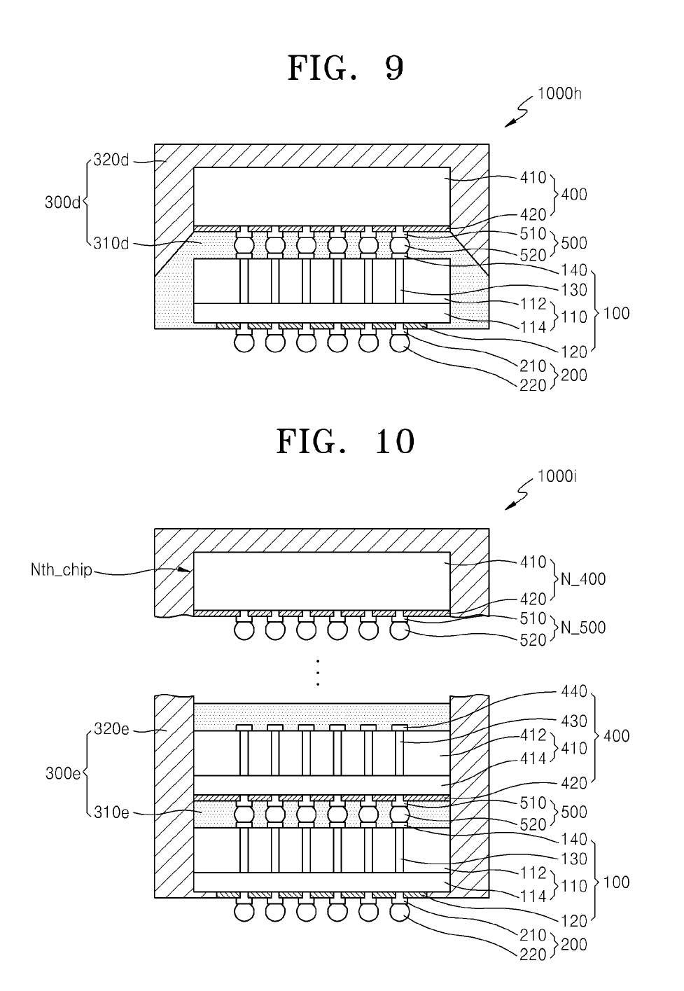

The semiconductor package 1000h of FIG. 9 has a similar structure to that of the semiconductor package 1000f of FIG. 7 except for an encapsulation member 300d. Thus, for convenience of description, the detailed description that has been described with reference to FIG. 7 is omitted or is simply described.

Referring to FIG. 9, in the semiconductor package 1000h, the encapsulation structure 300d may include an underfill 310d and an external encapsulation member 320d. The underfill 310d may be exposed from a lateral surface of an external encapsulation member 320d. For example, a lateral surface of the underfill 310d may correspond to a lateral surface of the external encapsulation member 320d.

A lower surface of the underfill 310d may be exposed as a lower surface of the semiconductor package 1000h. The underfill 310d of the encapsulation structure 300c may cover the exposed edge portion of the lower surface of the lower body layer 114. Thus, the lower surface of the underfill 310d may correspond to and be coplanar with the lower surface of the protective layer 120 of the first semiconductor chip 100. Thus, in the semiconductor package 1000h, a first semiconductor chip 100 may be encapsulated by the underfill 310d to have a locking structure.

The underfill 310d may be formed so that an increasing rate of a width of the underfill 310d is greater than that of the underfill 310 of FIG. 7. As such, a portion of the outer surface of the underfill 310d may be diagonal with respect to vertical side surfaces. In the presence of the underfill 310d, the external encapsulation member 320d may surround only lateral and upper surfaces of the second semiconductor chip 400.

The semiconductor package 1000i of FIG. 10 includes at least three stacked semiconductor chips, unlike in FIGS. 1 through 9. Thus, for convenience of description, the detailed description that has been described with reference to FIG. 1 through 9 is omitted or is simply described.

Referring to FIG. 10, the semiconductor package 1000i may include N semiconductor chips 100, 400, through Nth_chips, first through Nth connection members 200, 500, through N_500, and an encapsulation member 300e. Here, N is an integer equal to or greater than 3.

Each of the N semiconductor chips 100, 400, through Nth_chips except for the uppermost semiconductor chip Nth_chip may include TSVs 130 and 430, and upper pads 140 and 440 in order to electrically connect the N semiconductor chips 100, 400, through Nth_chips to each other. That is, since any semiconductor chip is not formed on the uppermost semiconductor chip Nth_chip, a TSV and an upper pad may be not formed in the uppermost semiconductor chip Nth_chip.

The first semiconductor chip 100 may include a first body layer 110 and a first protective layer 120. The first protective layer 120 may expose an edge portion of a lower surface of a lower body layer 114. In addition, in one embodiment, in each of the N semiconductor chips 100, 400, through Nth_chips except for the first semiconductor chip 100, a protective layer does not expose an edge portion of a lower surface of a body layer. Alternatively, in each of the N semiconductor chips 100, 400, through Nth_chips, the protective layer may also expose the edge portion of the lower surface of the body layer.

The encapsulation structure 300e may include an underfill 310e and an external encapsulation member 320e. The underfill 310e may be filled in spaces between the N semiconductor chips 100, 400, through Nth_chips. Instead of the underfill 310e, an NCF, an ACF, a UV film, instant adhesives, thermosetting adhesives, laser setting adhesives, supersonic wave setting adhesives, NCP, or the like may be filled in the spaces between the N semiconductor chips 100, 400, through Nth_chips.

The external encapsulation member 320e of the encapsulation structure 300e may cover lateral surfaces of the underfill 310e and the N semiconductor chips 100, 400, through Nth_chips, an upper surface of the uppermost semiconductor chip Nth_chip, and the exposed edge portion of the lower surface of the lower body layer 114 of the first semiconductor chip 100. Thus, a lower surface of the external encapsulation member 320e may correspond to and be coplanar with a lower surface of the first protective layer 120.

FIG. 10 shows that only the underfill 310e is formed on the second semiconductor chip 400 in order to indicate a chip unit. However, in the underfill 310e, upper pads 440 of the second semiconductor chip 400 may be connected to a connection member of an upper semiconductor chip. The underfill 310e may not be formed on the uppermost semiconductor chip Nth_chip.

Also in the semiconductor package 1000i, the encapsulation member of the encapsulation structure 300e covers the exposed edge portion of the lower surface of the lower body layer 114, thereby stably encapsulating the N semiconductor chips 100, 400, through Nth_chip to have a locking structure.

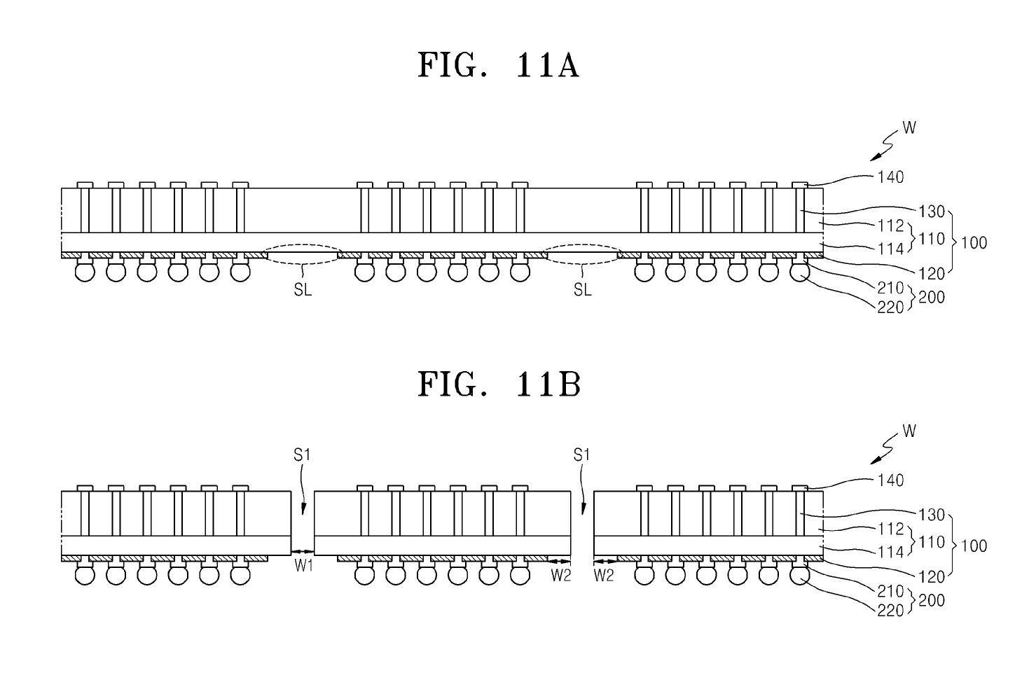

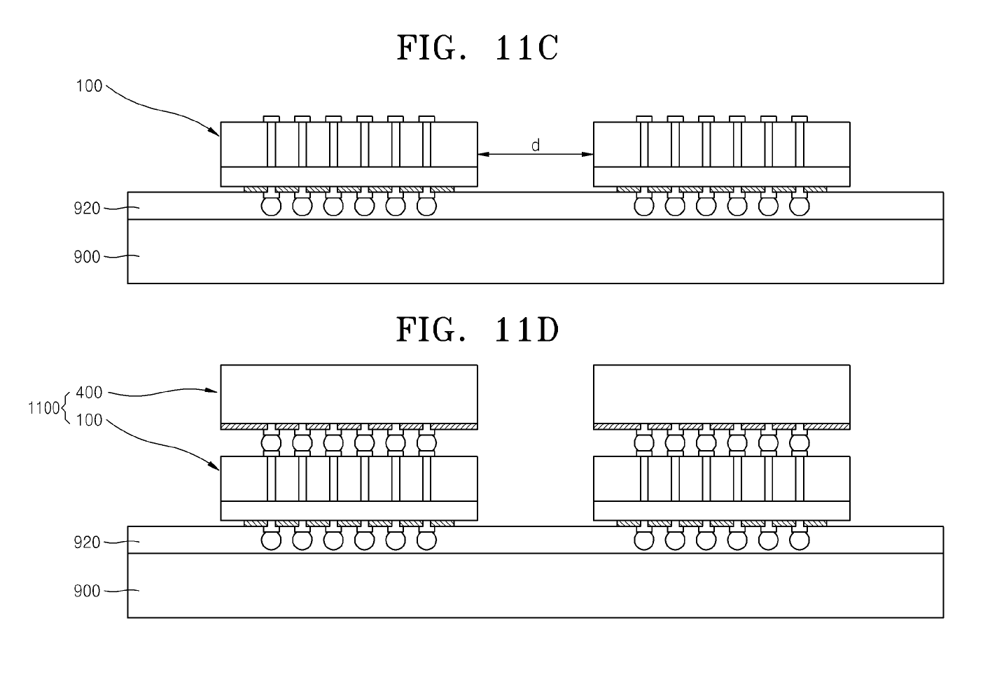

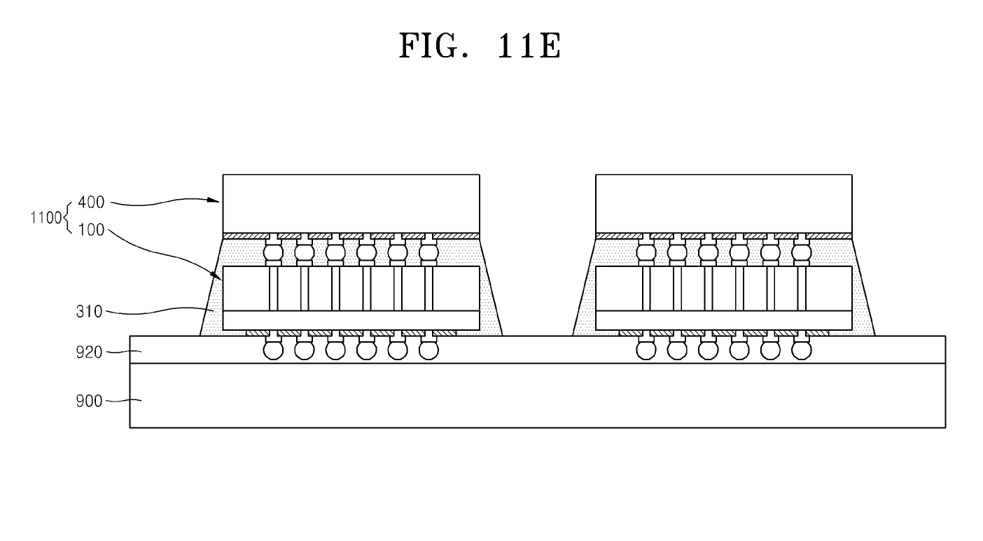

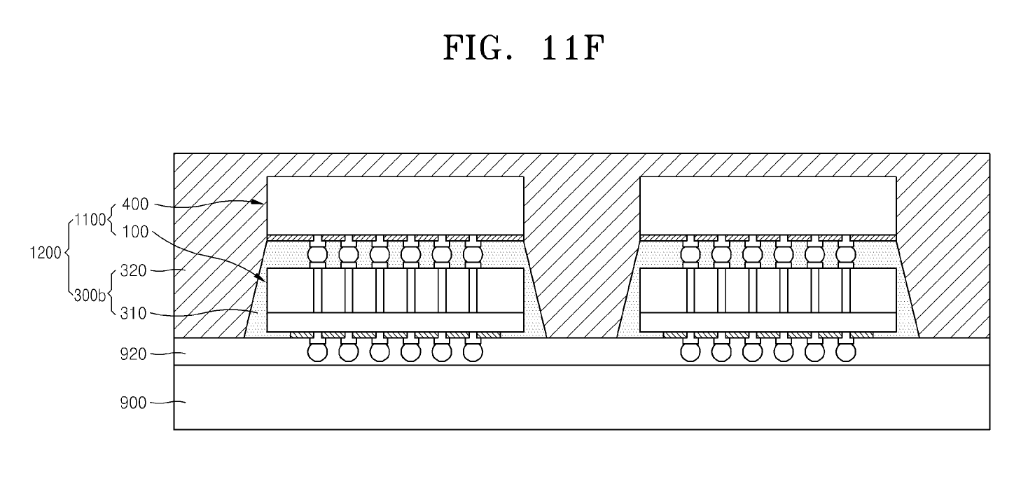

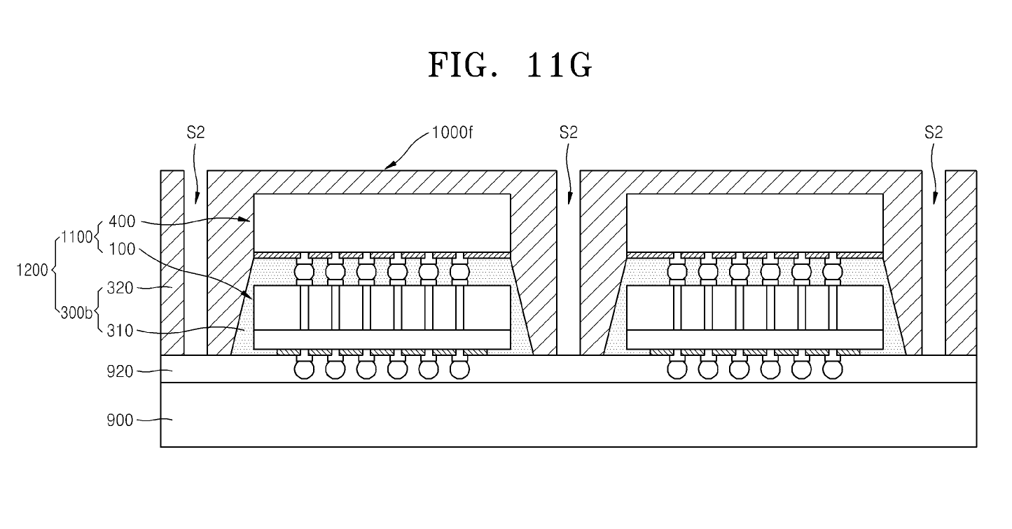

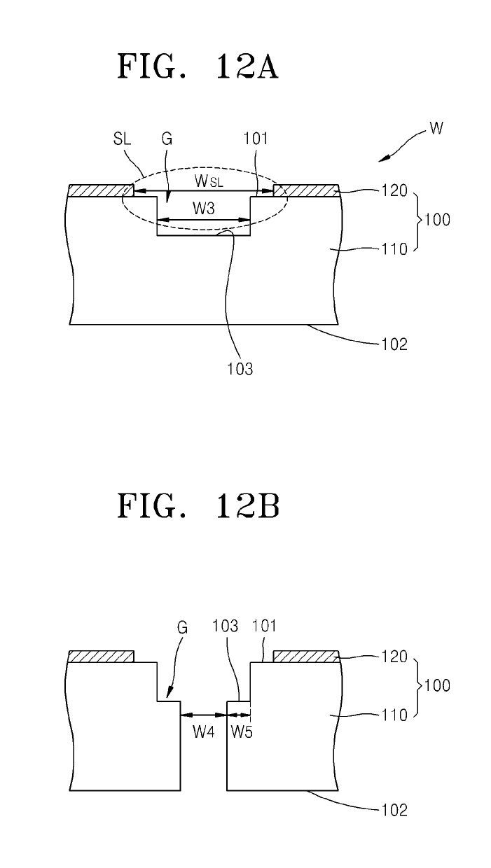

FIGS. 11A through 11G are cross-sectional views for describing a method of manufacturing the semiconductor package 1000f of FIG. 7, according to one embodiment.

Referring to FIG. 11A, a base wafer W including a plurality of semiconductor chips including TSVs 130 formed therethrough is prepared. The base wafer W may be prepared by attaching the base wafer W to a support substrate (not shown) by using an adhesive member (not shown). The base wafer W may be attached to the support substrate so that the first connection members 200 face the support substrate or the upper pads 140 face the support substrate.

The base wafer W may be prepared by simultaneously forming the semiconductor chips including the TSVs 130 formed therethrough in a wafer level. Each of the semiconductor chips may correspond to the first semiconductor chip 100 included in the semiconductor packages 1000b through 1000i of FIGS. 3 through 10. As shown in FIG. 11A, the protective layer 120 may be formed on a lower, bottom surface of the lower body layer 114 and in one embodiment, is not formed on scribe lanes (SLs) of the base wafer W.

Although not shown, the protective layer 120, which may be a passivation layer comprised, for example, of an insulating material, may be formed on the body layer 114 in different manners. For example, in one embodiment, the protective layer 120 is formed prior to forming of the connection terminal members 200, so that the protection layer 120 entirely covers a bottom surface of the body layer 114 within a circuit region of the semiconductor chip 100 and up to a scribe lane region SL. Subsequently, openings may be formed in the protective layer 120, using photolithography, mask patterns, etching, and/or other known methods, and a conductive material may be deposited in the openings to form part of the connection terminal members 200 (e.g., a bump pad 210). Alternatively, the protective layer 120 may initially also cover the scribe lane region SL, but that portion may be removed at the same time that the openings are formed.

In another embodiment, the protective layer 120 may be formed using a mask pattern so that when it is formed, it includes the openings and does not cover the SL region. Subsequently, the connection terminal members 200 can be formed. In yet another embodiment, the connection terminal members 200, or at least the bump pads 210, can be formed prior to forming the protective layer 120. The protective layer 120 can then be formed to cover remaining portions of the bottom surface of the body layer 114, but can only extend to the scribe lane region (or can initially cover the scribe lane region and can then be removed from the scribe lane region after being formed).

Referring to FIG. 11B, the semiconductor chips are divided by sawing the base wafer W along the SLs. The sawing may be performed, for example, by using a blade or a laser. Each of the semiconductor chips may correspond to the first semiconductor chip 100 of the semiconductor packages 1000b through 1000i of FIGS. 3 through 10. Thus, for convenience of description, the semiconductor chips of the base wafer W will be referred to as the “first semiconductor chip 100” or “first semiconductor chips 100”. ‘S1’ indicates portions that are divided by the sawing. A sawing width W1 may be determined according to a thickness of a blade. When a laser is used, the sawing width W1 may be much smaller than a sawing width when the blade is used.

In one embodiment, when the base wafer W is attached to the support substrate, the sawing is performed on the base wafer W only and may be not performed on the support substrate. The first semiconductor chips 100 of the base wafer W is divided and then the support substrate may be removed.

In each of the first semiconductor chips 100 that are divided by the sawing, an edge portion of a lower surface of the lower body layer 114 may be exposed. A width W2 of the exposed edge portion of the lower surface of the lower body layer 114 may be determined according to a thickness of a blade or laser used for the sawing. For example, if a width of the SL is about 50 μm, when the sawing is performed by using a blade, the width W2 of the edge portion of the lower surface of the lower body layer 114 may be equal to or less than 10 μm. When the sawing is performed by using a laser, the exposed edge portion of the lower surface of the lower body layer 114 may be about 25 μm.

Referring to FIG. 11C, the first semiconductor chips 100 are adhered onto a support carrier 900 by using an adhesive member 920. The support carrier 900 may be formed of silicon, germanium, silicon-germanium, gallium-arsenic (GaAs), glass, plastic, ceramic, or the like. In certain embodiments, the support carrier 900 may be formed as a silicon substrate or a glass substrate. The adhesive member 920 may be formed of an NCF, an ACF, a UV film, instant adhesives, thermosetting adhesives, laser setting adhesives, supersonic wave setting adhesives, NCP, or the like.

An aligning mark may be formed on the support carrier 900. The aligning mark may be a mark for indicating a portion to which semiconductor chips are adhered. The aligning mark may be formed to be recessed by etching the support carrier to form a trench by using a dry or wet etching method. Alternatively, the aligning mark may be formed by etching the support carrier to form a trench by using a dry or wet etching method, or a method with a laser, and filling a portion or entire portion of the trench with a metal material. Alternatively, the aligning mark may be formed by etching the support carrier to form a trench by using a dry or wet etching method, or a method with a laser, forming a metal material on an entire surface of the support carrier, and then polarizing the resulting structure by using a damascene process. In addition, the aligning mark may be formed to be embossed by forming a pattern on the support carrier and filling the pattern with a metal material.

The first semiconductor chips 100 may be adhered to the support carrier 900 so that the first connection members 200 may face the support carrier 900. In addition, the first semiconductor chips 100 may be arranged on the support carrier 900 with a predetermined interval d therebetween. The predetermined interval d may be appropriately determined according to a size of the semiconductor package.

According to one embodiment, since the first semiconductor chips 100 are arranged on the support carrier 900 with predetermined interval d, problems caused due to a width of a SL of a base wafer in underfill and sawing processes may be overcome. In addition, lateral surfaces of semiconductor chips may be completely encapsulated, thereby preventing the semiconductor chips from being physically and electrically damaged due to contamination, damage, interface delamination, and the like.

Referring to FIG. 11D, a chip stack 1100 is formed by stacking the second semiconductor chip 400 on each of the first semiconductor chips 100. The chip stack 1100 may be formed by adhering the second connection member 500 of the second semiconductor chip 400 onto the upper pads 140 of the first semiconductor chip 100 by using a thermo compressing method. The second semiconductor chip 400 may be stacked on each of the first semiconductor chips 100 by using an adhesive member such as an NCF, an ACF, a UV film, instant adhesives, thermosetting adhesives, laser setting adhesives, supersonic wave setting adhesives, NCP, or the like.

The second semiconductor chips 400 may be obtained by dividing a single base wafer into a plurality of semiconductor chips. In one embodiment, no TSVs are formed in the second semiconductor chips 400. However, if necessary, a TSV may be formed in the second semiconductor chips 400. In this case, the second semiconductor chips 400 may be semiconductor chips separated from a base wafer that is the same as the first semiconductor chips 100.

Referring to FIG. 11E, the underfill 310 is formed in a space between the first semiconductor chip 100 and the second semiconductor chip 400 of the stack chip 1100. The underfill 310 may be filled in only a space between the first semiconductor chip 100 and the second semiconductor chip 400. However, as shown in FIG. 11E, the underfill 310 may surround a lateral surface of the first semiconductor chip 100 while being filled in the space between the first semiconductor chip 100 and the second semiconductor chip 400. The underfill 310 may cover the exposed edge portion of the lower, bottom surface of a lower body layer of the first semiconductor chip 100. Thus, a lower surface of the underfill 310 may correspond to a lower surface of a first protective layer.

When the underfill 310 surrounds the first semiconductor chip 100, the underfill 310 may be spaced apart away from an underfill surrounding another first semiconductor chip 100 of another neighboring stack chip. However, the underfill 310 may be formed to overlap the underfill of the neighboring stack chip. In this case, after a semiconductor package is complexly manufactured, an underfill may be exposed from a lateral surface of an external encapsulation member, like in FIG. 9.

According to one embodiment, the underfill 310 is formed so that a width of the underfill 310d is increased downwards, but is not limited thereto. Thus, the underfill 310 may be changed in various ways. For example, as shown in FIG. 8, the underfill 310 may only fill in a space between the first and second semiconductor chips 100 and 400.

When a molded underfill (MUF) process is used, the underfill shown in FIG. 11E may be omitted.

Referring to FIG. 11F, the external encapsulation member 320 surrounding stack chips 1100 and the underfill 310 is formed. The underfill 310 and the external encapsulation member 320 may constitute the encapsulation structure 300b. The external encapsulation member 320 may cover a lateral surface of the underfill 310, and lateral and upper surfaces of the second semiconductor chip 400. In certain embodiments, as shown in FIGS. 1-6, an underfill need not be used. In addition, the same encapsulating steps discussed above can apply to a single chip, such as depicted in FIGS. 1 and 2.

The stack chips 1100 and the encapsulation member 300b may constitute a semiconductor package complex 1200, that includes a plurality of chip stacks disposed adjacent each other and covered by a single continuous encapsulation member.

Referring to FIG. 11G, the semiconductor packages 1000f are separated from each other by sawing the semiconductor package complex 1200. In the embodiment of FIG. 11G, the sawing is performed on the semiconductor package complex 1200 only. The adhesive member 920 may be partially removed by performing the sawing. Here, S2 refers to a portion that is divided by performing the sawing.

After the sawing is performed, the support carrier 900 and the adhesive member 920 are removed, thereby completing the semiconductor package 1000f. The support carrier 900 and the adhesive member 920 may be sequentially or simultaneously removed. For example, when the support carrier 900 is formed of a transparent material, for example, glass and the adhesive member 920 is formed of a UV film, the support carrier 900 and the adhesive member 920 may be simultaneously separated from the semiconductor package complex 1200 by irradiating UV rays.

Prior to separating the semiconductor packages 1000f from each other by performing the sawing, an electrical die sorting (EDS) test may be performed. When the EDS test is performed, the first connection members 200 need to be exposed to the outside. Thus, the semiconductor package complex 1200 may be detached from the support carrier 900, the semiconductor package complex 1200 is adhered to a support substrate (not shown), and then the ESD test may be performed. The semiconductor package complex 1200 may be adhered to the support substrate so that a surface of the semiconductor package complex 1200, on which the first connection members 200 are not formed, may face the support substrate.

The EDS test may be performed by using a probe card (not shown) or the like. The probe card may include a body portion (not shown) and a terminal pin (not shown). The terminal pin may be, for example, a pogo pin. When pogo pins contact the first connection members 200 and electrical signals are applied, the EDS test may be performed. Through the EDS test, whether the stack chip 1100 is defective or not may be determined. After whether the stack chip 1100 is defective or not is determined, a defective stack chip or semiconductor package may be discarded.

According to one embodiment, first semiconductor chips of a base wafer are arranged and adhered onto a support carrier with a predetermined sufficient interval and then a semiconductor package is formed by using a series of processes. Thus, by virtue of the sufficient interval between first semiconductor chips, a sufficient sawing width may be obtained in a process of separating semiconductor packages of FIG. 11G, thereby singulating semiconductor packages. In addition, the first semiconductor chips are arranged on the support carrier with a predetermined interval and then spaces between the first semiconductor chips may be filled with an encapsulation member or an underfill and upper encapsulation member combination. Thus, after the sawing is performed, lateral surfaces of the first semiconductor chips may not be exposed to the outside. Furthermore, the encapsulation structure covers the exposed edge portion of a body layer, thereby stably encapsulating semiconductor chips to have a locking structure.

According to one embodiment, problems caused due to a width of a SL of a base wafer in underfill and sawing processes may be overcome. In addition, problems with exposing silicon of a lateral surface of a semiconductor chip to the outside may be overcome. Moreover, semiconductor chips may be completely encapsulated with the locking structure, thereby preventing the semiconductor chips from being physically and electrically damaged.

FIGS. 12A and 12B are cross-sectional views for describing a method of forming a semiconductor chip having a double step difference, which is used in the semiconductor package 1000a or 1000e of FIG. 2 or 6, according to certain embodiments.

Referring to FIG. 12A, in one embodiment, a cut groove G having a predetermined depth is formed by sawing a SL of a wafer W by using a first blade (not shown) having a first thickness. The cut groove G may have a first width W3. The first width W3 may be the same as a first thickness of the first blade.

The first width W3 of the cut groove G may be smaller than a width W_{SL} of the SL. The cut groove G may be formed in a central portion of the SL (e.g., midway between outer side surfaces of protection layers of adjacent semiconductor chips). Thus, an upper surface of the SL and a lower surface of the cut groove G, that is, the first surface 101 and the third surface 103 may have a predetermined step difference.

Referring to FIG. 12B, the wafer W is divided into the first semiconductor chips 100 by sawing a central portion of the cut groove G by using a second blade (not shown) having a second thickness. The second thickness of the second blade may be smaller than the first thickness of the first blade. A sawing interval obtained with the second blade may be a second width W4. The second width W4 may be the same as the second thickness of the second blade.

A double step difference may be formed on a lateral surface of the first semiconductor chip 100 that is separated by performing the sawing with the second blade. That is, the third surface 103, the first surface 101, and an upper surface of the protective layer 120 may constitute a double step difference.

According to one embodiment, when the wafer W is divided into the first semiconductor chips 100, the second blade having the second thickness is used. Alternatively, a laser may be used. When the laser is used, a sawing interval may be smaller than the second width W4. Thus, a width W5 of the third surface 103 may be increased compared to a case where the second blade is used.

FIGS. 13A through 13C are cross-sectional views for describing a method of forming a semiconductor chip having a double step difference, which is used in the semiconductor package 1000a or 1000e of FIG. 2 or 6, according to another embodiment.

Referring to FIG. 13A, a photoresist (PR) pattern layer 700 is formed on the wafer W to cover the protective layer 120. The PR pattern layer 700 may expose a central portion of a SL of the wafer W therethrough.

Referring to FIG. 13B, the body layer 110 is etched, for example, is dry-etched to form the groove G having a predetermined depth by using the PR pattern layer 700 as a mask. The groove G may have a fourth width W6. A lower surface of the groove G may correspond to the third surface 103.

Referring to FIG. 13C, the wafer W is divided into the first semiconductor chips 100 by removing the PR pattern layer 700 and sawing the central portion of the groove G by using a blade (not shown) having a predetermined thickness. A sawing interval obtained by performing the sawing may be a fifth width W7. The fifth width W7 may be smaller than the fourth width W6 of the groove G and may be the same as the thickness of the blade.

A double step difference is formed on a lateral surface of each of the first semiconductor chips 100 that are separated from each other by performing the sawing with the blade. That is, the third surface 103, the first surface 101, and an upper surface of the protective layer 120 may constitute a double step difference.

According to one embodiment, the wafer W is divided into the first semiconductor chips 100 by using a blade. Alternatively, a laser may be used. When the laser is used, a sawing interval may be smaller than the fifth width W7. Thus, a width W8 of a third surface 103 may be increased compared to a case where the blade is used.

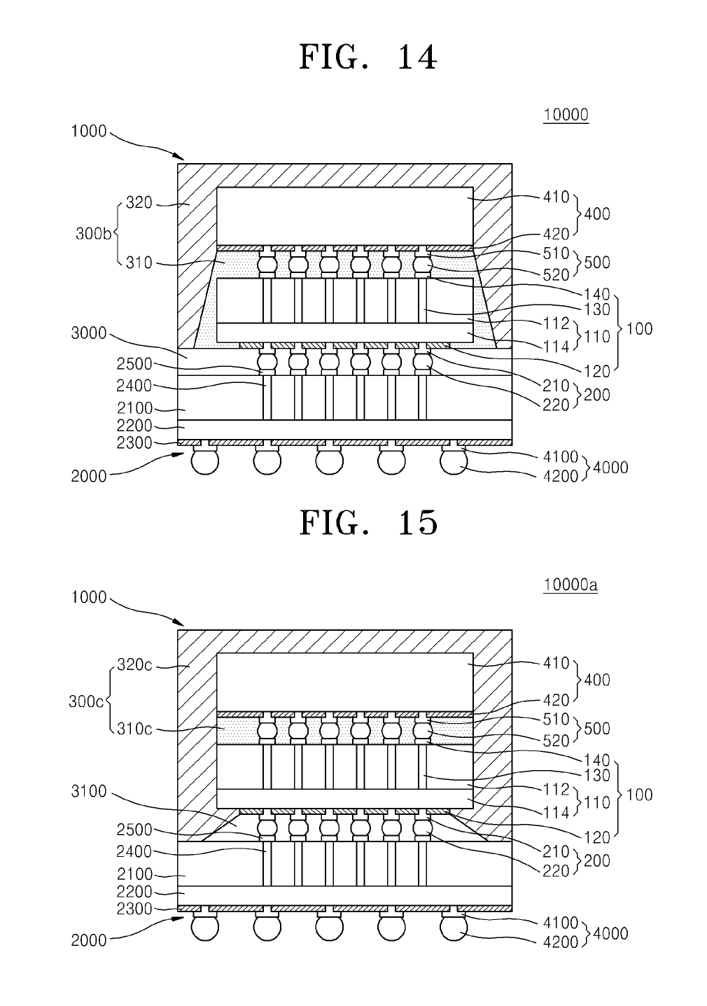

FIGS. 14 through 17 are cross-sectional views of semiconductor packages 10000, 10000a, 20000, and 30000 having a polymer locking structure, according to various embodiments.

Referring to FIG. 14, the semiconductor package 10000 may include a main chip 2000 and an upper semiconductor package 1000.

The upper semiconductor package 1000 may correspond to the semiconductor package 1000f of FIG. 7. Thus, the detailed description of the upper semiconductor package 1000 will be omitted or will be simply described.

The main chip 2000 may have a greater size than a size of each of the first and second semiconductor chips 100 and 400 included in the upper semiconductor package 1000. For example, a size of a horizontal sectional view of the main chip 2000 may be the same as a horizontal sectional view of the upper semiconductor package 1000 including the encapsulation structure 300b. The upper semiconductor package 1000 may be mounted on the main chip 2000 through an adhesive member 3000. Thus, a lower surface of the encapsulation structure 300b of the upper semiconductor package 1000 may be adhered to an edge portion of an upper surface of the main chip 2000 through the adhesive member 3000. Here, a lower surface of the external encapsulation member 320 and a lower surface of the underfill 310 may constitute a lower surface of the encapsulation structure 300b. In addition, the adhesive member 3000 may be formed of an NCF, an ACF, a UV film, instant adhesives, thermosetting adhesives, laser setting adhesives, supersonic wave setting adhesives, NCP, or the like. The adhesive member 3000 may be replaced by an underfill.

The main chip 2000 may include a body layer 2100, a lower insulating layer 2200, a protective layer 2300, TSVs 2400, and upper pads 2500. An IC layer (not shown) formed in the body layer 2100 and a plurality of wiring layers (not shown) formed in the lower insulating layer 2200 may be formed in various ways according to a type of the main chip 2000. The main chip 2000 may be a logic chip, for example, a central processing unit (CPU), a controller, an application specific integrated circuit (ASIC), or the like.

The number of the TSVs 2400 and the number of the upper pads 2500 corresponding to the TSVs 2400 may be determined according to the number of the first connection members 200 of the upper semiconductor package 1000 formed on the main chip 2000. Alternatively, if necessary, the number of TSVs 2400 may be greater than the number of the first connection members 200.

Third connection members 4000 may be formed on a lower surface of the main chip 2000. Each of the third connection members 4000 may include, for example, a bump pad 4100 and a bump 4200. The number of the third connection members 4000 may be smaller than the number of the TSVs 2400. Thus, a TSV 2400 that does not correspond to any third connection member may be commonly connected to a single third connection member 4000 through the wiring layers formed in the lower insulating layer 2200.

The third connection members 4000 may each have a greater size than that of the first connection member 200 of the upper semiconductor package 1000. This is because wirings formed in a board substrate (not shown) on which the main chip 2000 is mounted may be standardized or it may be difficult to densify the wirings due to material characteristics (e.g., plastic) of the board substrate. Thus, all the TSVs 2400 may not correspond to the third connection members 4000.

The semiconductor package 10000a of FIG. 15 may have a similar structure to that of the semiconductor package 10000 of FIG. 14 except for the structure and stacking relationship of the upper semiconductor package 1000. Thus, for convenience of description, the detailed description that has been described with reference to FIG. 14 is omitted or is simply described.

Referring to FIG. 15, in the semiconductor package 10000a, the upper semiconductor package 1000 has a similar structure to that the semiconductor package 1000g of FIG. 8. However, a main underfill 3100 may be filled in a space between the upper semiconductor package 1000 and the main chip 2000, and the encapsulation structure 300c may surround the main underfill 3100. For example, the external encapsulation member 320c of the encapsulation structure 300c may cover the exposed edge portion of a lower surface of the lower body layer 114 and may cover a lateral surface of the main underfill 3100. Thus, the external encapsulation member 320c may stably encapsulate the semiconductor chips 100 and 400 formed in the upper semiconductor package 1000 to have a locking structure. A lower surface of the encapsulation structure 300c and a lower surface of the main underfill 3100 may contact an upper surface of the main chip 2000.

When the main underfill 3100 is used, the upper semiconductor package 1000 may be stacked on the main chip 2000 by using a thermo compressing method. For example, the first connection members 200 of the upper semiconductor package 1000 may be stacked on the upper pads 2500 of the main chip 2000 by using a thermo compressing method. In order to mount the upper semiconductor package 1000 on the main chip 2000, an adhesive member may be used instead of the main underfill 3100.

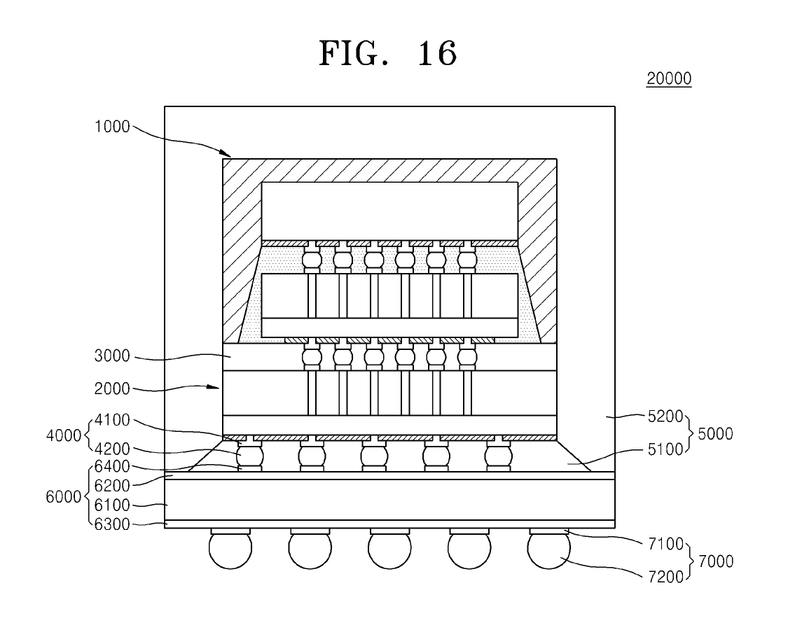

The semiconductor package 20000 of FIG. 16 may be configured so that the semiconductor package 10000 of FIG. 14 is mounted on a board substrate 6000.

Referring to FIG. 16, the semiconductor package 20000 may include the board substrate 6000, the main chip 2000, the upper semiconductor package 1000, fourth connection members 7000, and a second encapsulation structure 5000.

The upper semiconductor package 1000 and the main chip 2000 may have the same structure as in FIG. 14. Thus, the detailed description of the upper semiconductor package 1000 and the main chip 2000 will be omitted. The upper semiconductor package 1000 and the main chip 2000 may be mounted on the board substrate 6000 through the third connection members 4000.

The board substrate 6000 may include a body layer 6100, an upper protective layer 6200, a lower protective layer 6300, and upper pads 6400. A plurality of wiring layers may be formed in the body layer 6100. The upper protective layer 6200 and the lower protective layer 6300 may have a function of protecting the body layer 6100 and may each be, for example, a solder resist. As described above, in one embodiment, the board substrate 6000 is standardized and there is a limit in reducing a size thereof. Thus, the detailed description of the board substrate 6000 will be omitted.

The second encapsulation structure 5000 may include a second underfill 5100 and a second external encapsulation member 5200. The second external encapsulation member 5200 encapsulates lateral and upper surfaces of the upper semiconductor package 1000 and the main chip 2000. A lower surface of the second external encapsulation member 5200 may be adhered to edge portion of the board substrate 6000. The second underfill 5100 may be filled in a space between the main chip 2000 and the board substrate 6000. However, according to one embodiment, when the second encapsulation structure 5000 is formed by using a MUF process, the second underfill 5100 may be omitted.

Although not illustrated, the edge portion of the lower surface of the lower insulating layer 2200 of the main chip 2000 may be exposed through the protective layer 2300. The second encapsulation structure 5000 cover the exposed edge portion of the lower surface of the lower insulating layer 2200, and thus the second encapsulation structure 5000 may encapsulate the upper semiconductor package 1000 and the main chip 2000 to have a locking structure.

The fourth connection members 7000 may be disposed on a lower surface of the board substrate 6000 and may include a bump pad 7100 and a bump 7200.

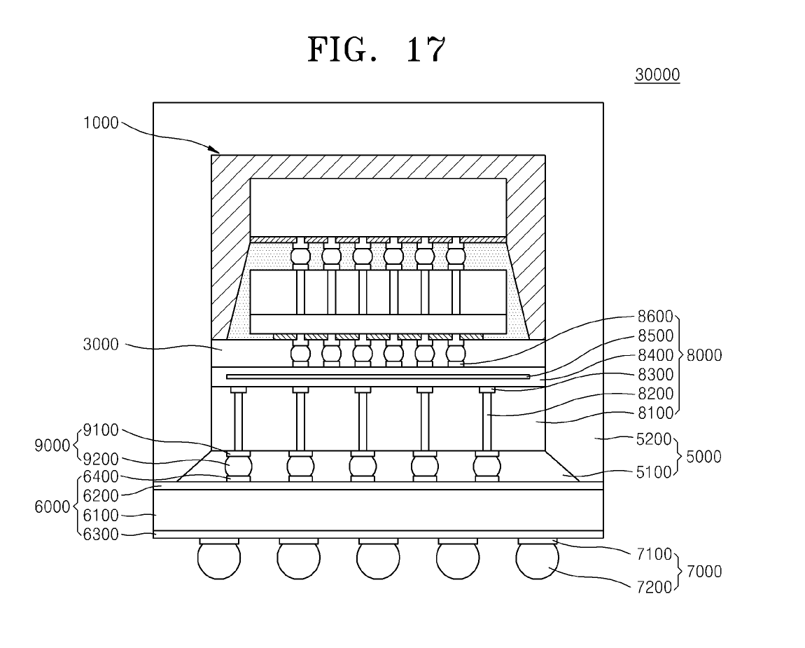

The semiconductor package 30000 of FIG. 17 may have a similar structure to that of the semiconductor package 2000 of FIG. 16 except for a main chip. Thus, for convenience of description, the detailed description that has been described with reference to FIG. 16 is omitted or is simply described.

Referring to FIG. 17, the semiconductor package 30000 may include an interposer 8000 instead of a main chip. Thus, an upper semiconductor package 1000 may be mounted on an interposer 8000 and the interposer 8000 may be mounted on a board substrate 6000.

The interposer 8000 may include a body layer 8100, TSVs 8200, upper pads 8300, an upper insulating layer 8400, a wiring layer 85000, and wiring pads 8600. The interposer 8000 may serve as a medium for mounting the upper semiconductor package 1000 that is miniaturized on the board substrate 6000.

The body layer 8100 is a simply a support substrate and may be formed of, for example, silicon, glass, ceramic, plastic, or the like. The TSVs 8200 may be formed through the body layer 8100. Ends of each of TSVs 8200 may be connected to the upper pads 8300 and third connection members 9000 that may be disposed on a lower surface of the interposer 8000 and may each include a bump pad 9100 and a bump 9200.

The upper insulating layer 8400 may be formed on the body layer 8100 and the upper pads 8300 and may be formed of an insulating material, for example, oxide or nitride.

The wiring layer 8500 is formed in the upper insulating layer 8400 and may electrically connect the upper pads 8300 to the wiring pads 8600.

The wiring pads 8600 may be formed on the upper insulating layer 8400. The number of the wiring pads 8600 may correspond to the number of the first connection members 200 of the upper semiconductor package 1000. Intervals between the TSVs 8200, intervals between the upper pads 8300, and intervals between the third connection members 9000 may each be greater than intervals between the wiring pads 8600 because the TSVs 8200, the upper pads 8300, and the third connection members 9000 may be standardized according to the board substrate 6000, as descried with FIG. 16. Although the intervals between the upper pads 8300 may not correspond to the intervals between the wiring pads 8600, a wiring structure of the wiring layer 8500 may overcome this problem.

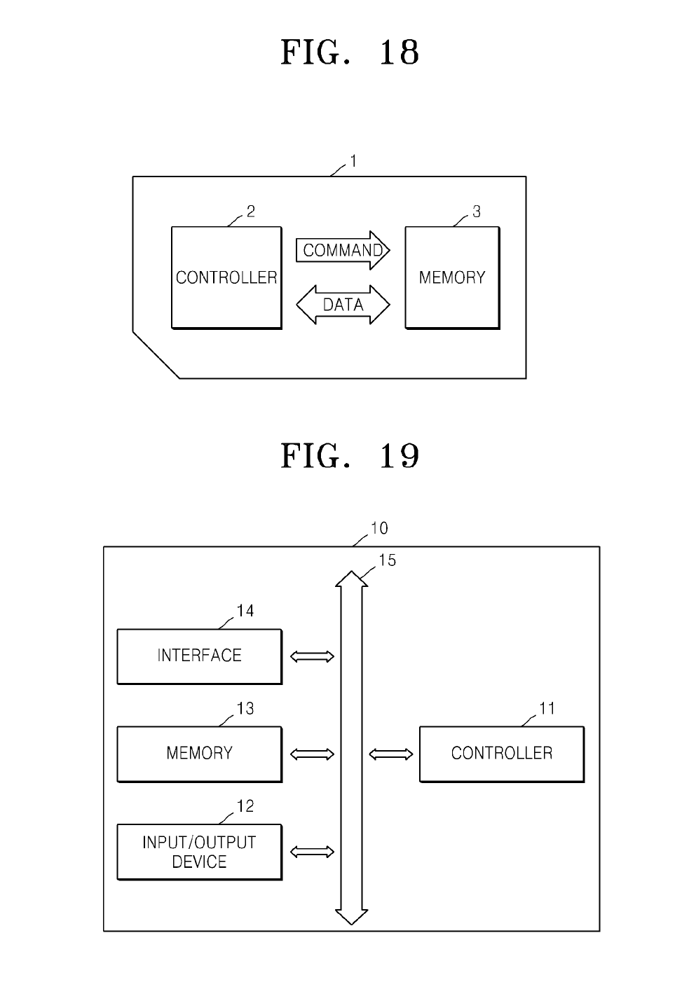

FIG. 18 is a block diagram of a memory card 1 including a semiconductor package according to one embodiment.

Referring to FIG. 18, a controller 2 and a memory 3 may be arranged in the memory card 1 so as to exchange electrical signals. For example, when the controller 2 gives a command, the memory 3 may transmit data. The controller 2 and/or the memory 3 may include the semiconductor package having a polymer locking structure and corresponding to one of the semiconductor packages 1000, 1000a, 1000b, 1000c, 1000d, 1000e, 1000f, 1000g, 1000h, 1000i, 10000, 10000a, 20000, and 30000 of FIGS. 1 through 10 and 14 through 17. The memory 3 may include a memory array (not shown) or a memory array bank (not shown).

The memory card 1 may be used in memory devices such as various types of cards, for example, memory stick cards, smart media cards (SMs), secure digital cards (SDs), mini secure digital cards (mini SDs), or multimedia cards (MMCs).

FIG. 19 is a block diagram of an electronic system 10 including a semiconductor package according to an embodiment of the inventive concept.

Referring to FIG. 19, the electronic system 10 may include a controller 11, an input/output device 12, a memory 13, and an interface 14. The electronic system 10 may be a mobile system or a system for receiving or transmitting information. Examples of the mobile system may include a personal digital assistant (PDA), a portable computer, a web tablet, a wireless phone, a mobile phone, a digital music player, or a memory card.

The controller 11 may execute a program and may control the electronic system 10. Examples of the controller 11 may include a microprocessor, a digital signal processor, a microcontroller, or a similar device. The input/output device 12 may be used to input or output data of the electronic system 10.

The electronic system 10 may be connected to an external device, for example, a personal computer or a network, by using the input/output device 12 and may exchange data with the external device. Examples of the input/output device 12 may include a keypad, a keyboard, or a display. The memory 13 may store a code and/or data for an operation of the controller 11 and/or may store data that is processed in the controller 11. The controller 11 and/or the memory 13 may include a semiconductor package having a polymer locking structure and corresponding to one of the semiconductor packages 1000, 1000a, 1000b, 1000c, 1000d, 1000e, 1000f, 1000g, 1000h, 1000i, 10000, 10000a, 20000, and 30000 of FIGS. 1 through 10 and 14 through 17. The interface 14 may serve as a data transmission path between the electronic system 10 and the external device. The controller 11, the input/output device 12, the memory 13, and the interface 14 may communicate with each other through a bus 15.

The electronic system 10 may be used in, for example, a mobile phone, an MP3 player, a navigation device, a portable multimedia player (PMP), a solid state disk (SSD), or a household appliance.

While the present disclosure has been particularly shown and described with reference to exemplary embodiments thereof, it will be understood that various changes in form and details may be made therein without departing from the spirit and scope of the following claims.

What is claimed is:

1. A semiconductor package comprising:
a first semiconductor chip comprising a first body layer having a first surface, a second surface, and a lateral surface between the first surface and the second surface, and a first protective layer that exposes an edge portion of the first surface and forms a step difference with the first surface;
an encapsulation structure that covers a lateral surface of the first body layer and the edge portion of the first surface so as to encapsulate the first semiconductor chip to have a locking structure; and
a first conductive terminal formed on the first body layer through the protective layer.

2. The semiconductor package of claim 1, wherein a bottom surface of the encapsulation structure is coplanar with a bottom surface of the first protective layer.

3. The semiconductor package of claim 1, wherein a third surface forming a step difference with the first surface is formed on the first body layer,
wherein the third surface, the first surface, and the first protective layer constitute a double step difference, and
wherein the encapsulation structure covers the third surface.

4. The semiconductor package of claim 1, further comprising at least one upper semiconductor chip stacked on the first semiconductor chip.

5. The semiconductor package of claim 4, wherein the at least one upper semiconductor chip comprises a single second semiconductor chip,
wherein the semiconductor package comprises a second conductive terminal formed on a bottom surface of the second semiconductor chip,
wherein the first semiconductor chip includes a through via that is electrically connected to the first conductive terminal,
wherein the second semiconductor chip is electrically connected to the through via through the second conductive terminal,
wherein the encapsulation structure is filled in a space between the first and second semiconductor chips, and
wherein the encapsulation structure covers lateral and top surfaces of the second semiconductor chip.

6. The semiconductor package of claim 4, wherein the encapsulation structure comprises an underfill that is filled in a space between the first semiconductor chip and a first chip of the at least one upper semiconductor chip, and an external encapsulation member that covers at least part of the underfill.

7. The semiconductor package of claim 6, wherein the external encapsulation member covers lateral surfaces of the first semiconductor chip and lateral surfaces of at least the first chip of the at least one upper semiconductor chip, an upper surface of an upper-most semiconductor chip of the at least one upper semiconductor chip, and an edge portion of the first surface.

8. The semiconductor package of claim 1, wherein the first protective layer is a nitride-based protective layer or a PSPI protective layer, and
wherein the encapsulation structure is formed of at least a polymer.

9. A semiconductor device, comprising:
at least a first semiconductor chip, the first semiconductor chip including a top surface, a bottom surface, and a lateral surface between the bottom surface and top surface, the first semiconductor chip further including a protective layer at the bottom surface,
wherein the protective layer is not formed at a first edge portion of the bottom surface of the first semiconductor chip adjacent the lateral surface; and
an encapsulation structure, the encapsulation structure covering the first edge portion of the bottom surface of the first semiconductor chip, and at least a first part of the lateral surface of the first semiconductor chip.

10. The semiconductor device of claim 9, wherein the protective layer is formed of one or more first materials, and the encapsulation structure is formed of one or more second materials different from the one or more first materials.

11. The semiconductor device of claim 10, wherein the encapsulation structure contacts the bottom surface of the semiconductor chip, a lateral surface of the protective layer, and the lateral surface of the semiconductor chip.

12. The semiconductor device of claim 11, wherein the encapsulation structure includes a homogenous material that contacts the bottom surface of the semiconductor chip, the lateral surface of the protective layer, and the lateral surface of the semiconductor chip.

13. The semiconductor device of claim 10, wherein the one or more first materials includes at least one of: an oxide material and a nitride material, and the one or more second materials includes at least one of: a resin, a silica filler, and a flux.

14. The semiconductor device of claim 9, wherein a bottom surface of the protective layer forms a bottom-most surface of the first semiconductor chip, and the bottom surface of the protective layer, a lateral surface of the protective layer, and the bottom surface of the first semiconductor chip at the first edge portion forms a step difference.

15. The semiconductor device of claim 9, wherein the first edge portion of the first semiconductor chip includes a first groove, and the encapsulation structure contacts the first semiconductor chip at surfaces of the first groove.

16. The semiconductor device of claim 9, further comprising:
a second semiconductor chip stacked on the first semiconductor chip, wherein the first semiconductor chip and the second semiconductor chip are part of a semiconductor package.

17. The semiconductor device of claim 16, wherein the encapsulation structure encapsulates both the first semiconductor chip and the second semiconductor chip.

18. The semiconductor device of claim 17, wherein the encapsulation structure fills in a space between the first semiconductor chip and the second semiconductor chip.

19. A method of manufacturing a semiconductor device, the method comprising:
forming at least a first semiconductor chip, the first semiconductor chip including a top surface, a bottom surface, and a lateral surface between the bottom surface and top surface,
wherein forming the first semiconductor chip includes forming a protective layer at the bottom surface of the semiconductor chip, wherein the protective layer does not cover at least an edge portion of the bottom surface of the first semiconductor chip; and
forming an encapsulation structure to cover the edge portion of the bottom surface of the first semiconductor chip, and at least a first part of the lateral surface of the first semiconductor chip.

20. The method of claim 19, wherein:
a bottom surface of the protective layer, a lateral surface of the protective layer, and the bottom surface of the first semiconductor chip at the edge portion form a step difference; and
forming the first semiconductor chip includes forming a first conductive terminal to pass through the protective layer.
